(19) United States
(12) Patent Application Publication
(10) Pub. No.: US 2016/0209459 A1
(43) Pub. Date: Jul. 21, 2016

(54) DIAGNOSTIC METHOD FOR AUTOMATIC DISCRIMINATION OF PHASE-TO-GROUND PARTIAL DISCHARGE, PHASE-TO-PHASE PARTIAL DISCHARGE AND ELECTROMAGNETIC NOISE

(71) Applicant: CAMLIN TECHNOLOGIES LIMITED, Lisburn Antrim (GB)

(72) Inventors: Marco Tozzi, Bologna (IT); Enrico Savorelli, Caderara di Reno (IT); Alessandro Salsi, Caderara di Reno (IT)

(21) Appl. No.: 14/913,720

(22) PCT Filed: Aug. 12, 2014
(86) PCT No.: PCT/EP2014/067281

§ 371 Date: Feb. 23, 2016

(30) Foreign Application Priority Data
Aug. 23, 2013 (GB) 1315089.1

(51) Int. Cl. G01R 31/14; G01R 31/12

(52) U.S. Cl. CPC G01R 31/14; G01R 31/1227

(57) ABSTRACT

A method of identifying partial discharge events in a multi-phase electrical supply. The method comprises measuring characteristics of each phase of the electrical supply in respect of a common measurement period; comparing the respect characteristics across the phases; and determining from the comparison if the respective characteristics are indicative of a partial discharge event or of the presence of electrical noise. The method allows automatic rejection of noise, and identification of phase to ground and phase to phase partial discharge. The comparison of characteristics may be performed using ternary diagrams, which facilitates performance of the method by unskilled persons.

### FIELD OF INVENTION

The present invention relates to the identification of partial discharge (PD) events in a multi-phase electrical supply. The invention relates particularly to a method of automatically identifying phase-to-phase PD, phase-to-ground PD and electrical noise.

### BACKGROUND TO THE INVENTION

Partial discharge (PD) measurement is a key factor to assess the condition of the insulation system in power transformers, cables, generators, switchgears, circuit breaker and motors. Whenever the voltage is applied to the equipment under test (EUT), an electrical field can be induced across localized defects inside or at the surface of the insulation causing local electrical stress concentrations. When the induced electrical field exceeds the local dielectric strength, Partial Discharges can occur appearing as pulses having duration significantly shorter than 1 us. The repetition rate and amplitude of those pulses may vary significantly depending on insulation material, insulation age, defect size, environmental conditions and applied voltage.

By connecting a measuring instrument to proper sensors installed in the EUT it is possible to record the Partial Discharge pulses and perform a statistical analysis aimed at understanding the presence, the nature and location of a defect. The PD measurement is generally carried out in shielded rooms in the factory, as part of the acceptance test in low-noise conditions. The same test carried out in the field can be challenging due to the presence of noise having strong amplitude and repetition rate, which can cover the Partial Discharge activity.

Appropriate algorithms and hardware may be used in order to collect all the pulses (noise and PD) over time and recognize which pulses are those related to noise and which to PD. Several methods of PD detection rejecting the noise are already described in literature but all of them present significant limitations when applied in the field. Indeed, most of the methods are able to extract meaningful parameters from the recorded waveforms in order to generate clusters in an image space where each cluster is correlated to signals coming from the same source (see for example U.S. Pat. No. 8,055,459, WO 2009013639, US 20080088314 and EP 2204660); the assumption is that concentrations of pulses having similar features are generated from the same source, which may be either noise or PD; anyway, once these concentration are created there is not any kind of automatic feature able to automatically and successfully understand which cluster is related to noise and which to PD. This is due because the clusters can change positions in the 2-D map case by case (depending on the electrical asset (equipment), the voltage, the sensors, and many other factors) and, also, it may happen that sometimes the noise and PD clusters can be very close each-other making their separation difficult even to expert operators. In particular, the main limitations of such methods are:
1. To identify if a cluster is correlated to a Partial discharge or to noise it is necessary to manually select the cluster, which means that operator intervention is necessary, resulting possibility of mistakes done by unskilled operators
2. Once the clusters are manually selected, further different graphical representations (Phase-Resolved Partial Discharge plot, NqN plot, etc. . . . ) are used to address the selected cluster as noise or PD. Such identification is done either using complex automatic algorithms based on fuzzy logic and neural networks, or by means skilled operator intervention.
3. In case the selected cluster is addressed as PD, there is no automatic feature available nowadays to further address the PD as phase-to-ground or phase-to-phase phenomenon
4. There is no immediate correlation between the position of the clusters within the image space and the source of the phenomenon. Clusters relevant to noise sources can occupy different areas within the image space or can be centered in always the same point but the boundaries of the occupied area around this point are erratic and can changes significantly over the time

### SUMMARY OF THE INVENTION

To improve the limitations mentioned above, from one aspect preferred embodiments of the present invention provide a method for automatically rejecting the electromagnetic noise and external disturbances affecting Partial Discharge measurement in electrical assets, without any need for operator intervention.

The preferred method is based on the study of shape parameters (or characteristics) deriving from respective electrical signals simultaneously acquired in the three phases of the electrical supply to the equipment under test (EUT). The simultaneous acquisition of signal data for each phase makes it possible to understand if detected events are related to noise or to a single phase event or to a phase to phase event. A triad of analogue signals is recorded simultaneously in the three phases of the EUT, generating a corresponding triad of shape parameter (or signal characteristic) values. The time between each acquisition should be set as low as possible, preferably in the range of microseconds.

Accordingly, one aspect of the invention provides a method as claimed in claim 1.

A second aspect of the invention provides an apparatus as claimed in claim 2.

Preferred features are recited in the dependent claims.

A general assumption for the preferred method is that signals, acquired simultaneously in the same instant (or in respect of the same measurement period) in each of the three phases of the EUT, having the same shape characteristic(s) are related to electro magnetic noise, which is originated from an external source coupled in a similar way to each of the three phases of the EUT. All the signals having different shape parameters in the three phases of EUT are assumed to relate to a Partial Discharge event.

In preferred embodiments, the method involves, processing electrical signals acquired from sensors coupled to the three phases (e.g. to a respective conductor of each phase) of high and/or medium voltage electrical assets, aimed at automatically rejecting the signals correlated to noise sources and identifying those signals correlated to phase-to-ground or phase-to-phase activities. The preferred method involves determination of meaningful shape parameters of the respective waveforms of the respective signal for each phase, simultaneously detected on each of the three phases of the Equipment Under Test (EUT). For each detected signal, one for each of the phases of the EUT, the same shape parameter (i.e. a corresponding signal characteristic) is calculated generating a triad of shape parameters; the three shape parameters are then converted in relative concentrations (normalized), e.g. expressed in percentages, and preferably plotted on a ternary diagram, which is used as a graphical device to allow target identification, where seven regions are segmented to define identification areas and allow automatic separation of noise/PD events. The noise, which lies in the central area, is separated easily. Further discrimination within the separate PD events occurring in just one or two phases is possible. Also provided is a method to accomplish automatic classification of the recorded signals without operator intervention. The method can be applied to any kind of medium and high voltage three-phase electrical asset in both on-line and off-line conditions.

While the invention is particularly suited in application to 3 phase AC electrical supplies, it will be apparent that it may alternatively be applied more generally to a multi-phase (AC) electrical supply.

Preferred embodiments of the present invention allow for automatic rejection of the electromagnetic noise and external disturbances affecting the Partial Discharge measurement in electrical assets, such as power transformers, instrument transformers, cables, switchgears, circuit breakers, generators and motors. Furthermore, events which are not addressed as noise can be automatically identified as events originated from phase-to-phase or phase-to-ground sources. In a particularly preferred embodiment, the method involves acquiring simultaneously analogue signals from three sensors each coupled to a respective one of the three phases of the Equipment Under Test (EUT); converting the analogue signals into digital signals; extracting a meaningful shape parameter (e.g. peak amplitude of the absolute value of the digital signal, and/or other signal characteristic) for each digital signal to provide a group of shape parameters, where each parameter of the group is associated with one phase of the EUT; normalizing the value of each shape parameter (for example to the sum of the values of all the three parameters), providing an indication of the relative parameter proportion for each phase of the EUT; preferably plotting the triad of concentrations in ternary diagrams, where one point represents a combination of the three concentrations and may fall in one specific area among seven possible identification areas; identifying the triad of recorded signal parameters as noise, phase-to-phase PD or Phase-to-ground PD based on the position of the respective point with respect to the seven identification areas (or otherwise by comparing the normalized parameter values); advantageously giving a “false” output in the case where the triad of shape parameters generates a point within the ternary plot falling into the A7 area (or otherwise indicate the presence of noise); preferably giving a “true” output in the case where the triad of shape parameters generates a point within the ternary plot falling in any area different from A7 (or otherwise indicate the presence of a PD event); in case of “true” output, determining and preferably indicating if the recorded event is phase-to-ground or phase-to-phase depending on which is the area where the point is falling in (or otherwise by comparing the normalized parameter values); preferably rejecting the entire set of recorded signals in case the output is “false”.

### BRIEF DESCRIPTION OF THE DRAWINGS

Embodiments of the invention are now described by way of example and with reference to the accompanying drawings in like numerals are used to indicate like parts and in which:

FIGS. 1A to 1C show representations of signals acquired simultaneously in the three phases of an EUT, related to a single phase-ground event (FIG. 1A), phase-to-phase event (FIG. 1B) and noise (FIG. 1C);

FIGS. 2A to 2C show respective versions of Ternary diagrams based on thresholds t1, t2, t3 and t4 segmenting seven well defined areas;

FIG. 3 shows a block diagram illustrating a preferred method and apparatus embodying aspects of the invention;

FIGS. 4A to 4C show respective Ternary plots segmented using t1=40, t2=40, t3=10, t4=50, FIG. 4A showing a case where there are three phase to ground sources and noise, FIG. 4B showing presence of just noise, and FIG. 4C showing presence of noise and one phase-to-ground phenomenon;

FIGS. 5A and 5B show respective sets of three captured phase signals, FIG. 5A representing a Low-Mid noise situation where the PD pulse has significantly greater amplitude than noise, and FIG. 5B representing a high noise condition where the noise amplitude is comparable to that of PD;

FIG. 6 shows a block diagram illustrating another preferred method embodying aspects of the invention based on the combination of three parameters: A, ES, APSD;

FIG. 7 is a schematic diagram illustrating embodiments of the invention in situ; and

FIG. 8 illustrates a preferred method of detecting the presence of PD events based on amplitude proportion values.

### DETAILED DESCRIPTION OF THE DRAWINGS

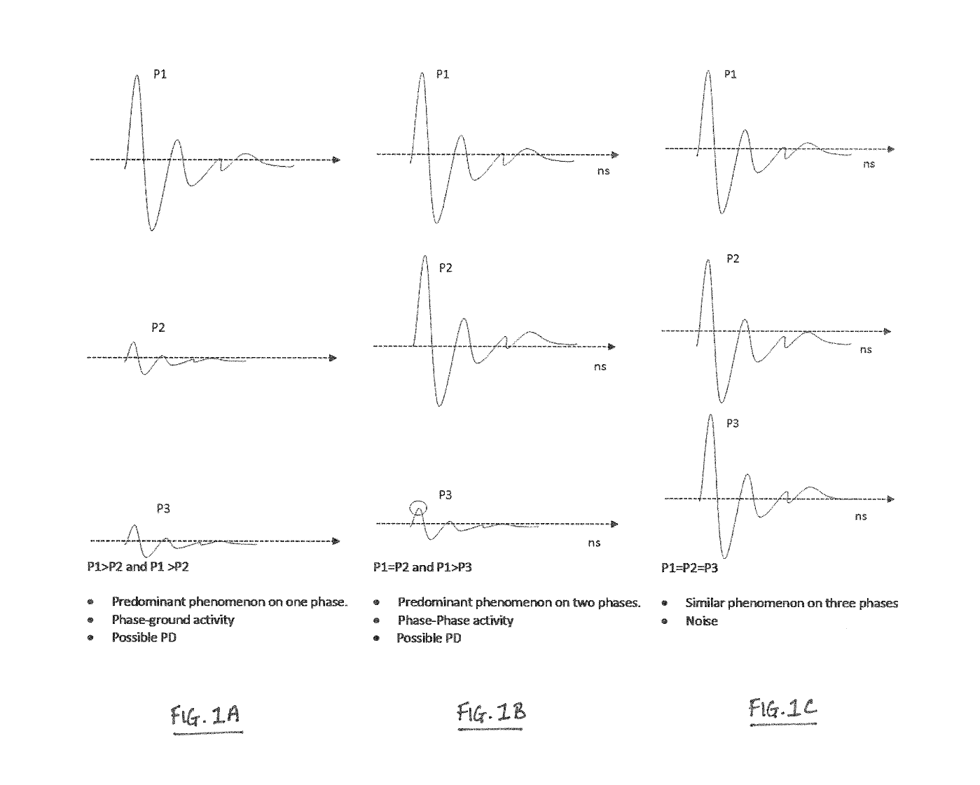

FIGS. 1A to 1C show representations of signals acquired simultaneously in the three phases of an EUT, related to a single phase-ground event (FIG. 1A), phase-to-phase event (FIG. 1B) and noise (FIG. 1C). In order to extract the peak amplitude of the electrical signals as a meaningful shape parameter (characteristic) from digital signals, the following assumptions may be made: Electromagnetic noise is generally coupled with the three phases of the EUT in a similar way. This means that the amplitude (P) of the noise detected in the three channels will be very similar, i.e. P1≈P2≈P3; Phase to phase PD phenomena are similar on two phases which means that they can have very similar amplitude in two phases, but significantly higher than the third one; A phase-ground PD event will be significantly bigger (higher amplitude) in the phase where the source is located.

In order to translate in mathematical language words like “very similar” or “significantly higher” or “bigger” it is necessary to define thresholds values to be compared to the shape parameters extracted from each triad of acquired signals. For this purpose ternary diagrams are preferably used, which allow an easy way to set and modify thresholds.

A ternary diagram (also known as a triangular plot or ternary plot) is a graphical plot based on the use of an equilateral triangle. It is used for displaying the relationship between three variables that are related in a manner such that their sum is equal to 1 or to 100%. The three variables are commonly referred to as end-members. Each apex of the triangle represents 100% of an end-member and the side of the triangle opposite a particular apex represents 0%. A point in the centre of the triangle represents equal proportions (%) of all three end-members.

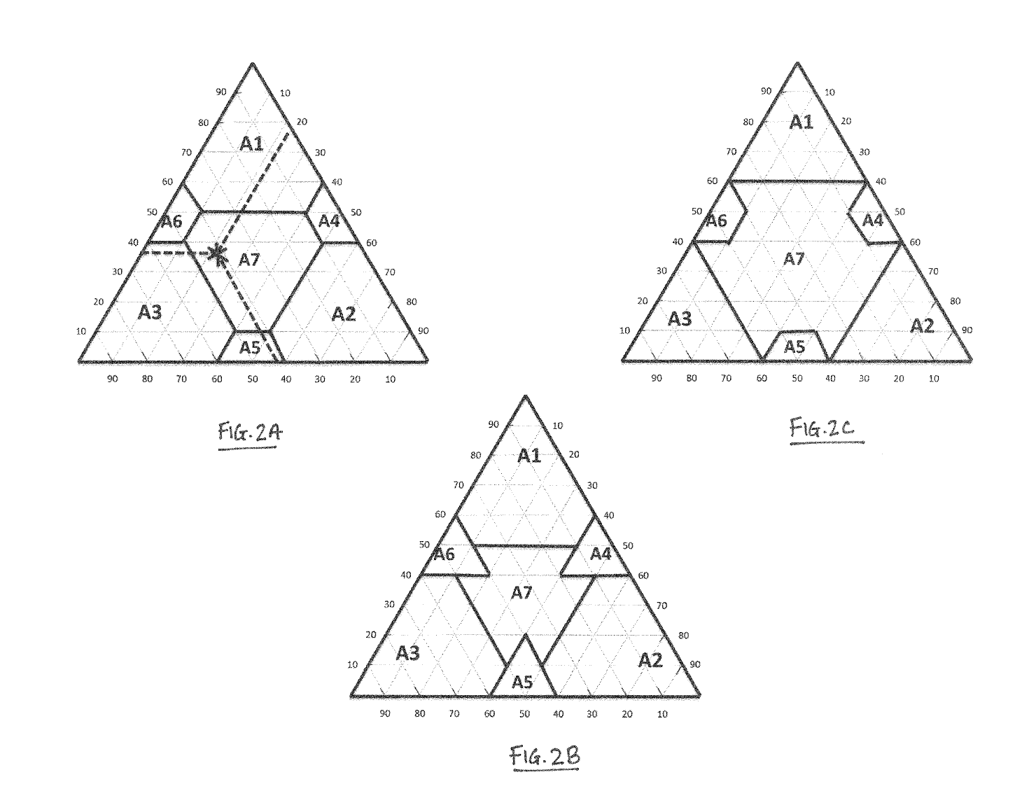

FIGS. 2A to 2C show respective versions of a ternary diagram segmented into seven areas A1 to A7. In the preferred method, the end-members correspond to single phase phenomena occurring only in phase 1 (left side of ternary diagram as viewed in FIG. 2), phase 2 (right side of ternary diagram as viewed in FIG. 2) and phase 3 (bottom side of ternary diagram as viewed in FIG. 2) of the EUT respectively. The seven areas A1 to A7 are designated as corresponding to the following activities: phase-to-ground activities (areas A1, A2 and A3), phase-to-phase activities (areas A4, A5 and A6) and noise area (A7).

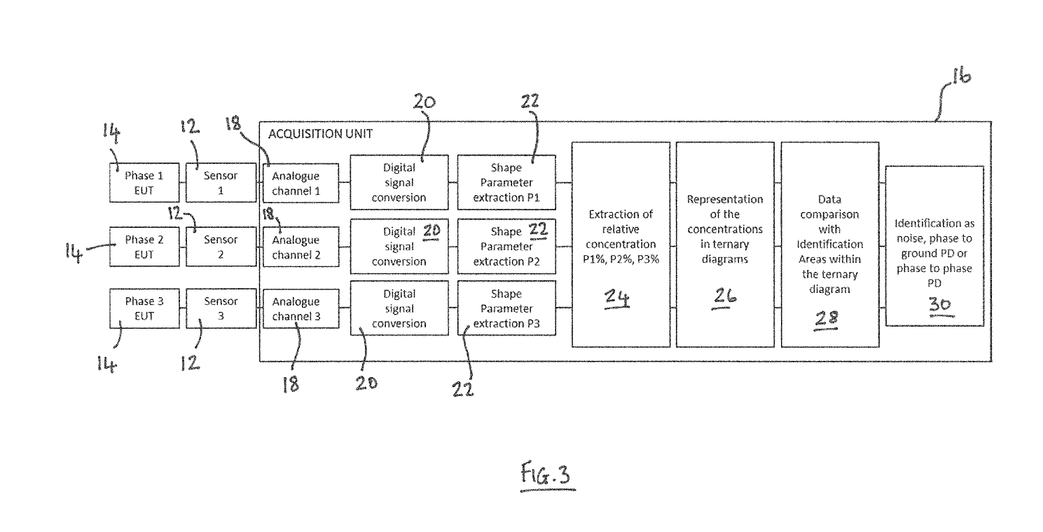

The general block diagram of the preferred apparatus and process is shown in FIG. 3. Analogue signals are simultaneously detected by three sensors 12, each one connected to a respective phase 14 of the EUT (not shown) and supplied to an acquisition unit 16. The sensors 12 are connected to three simultaneous channels 18 of the acquisition unit 16 (or measuring instrument), and the respective analogue signals are converted into digital signals by a digital signal converter 20. An amplitude parameter P (e.g. max peak of the absolute value of the signal) is extracted from each digital signal by a parameter extractor 22, resulting in a triad of amplitudes (P1, P2, P3), each one corresponding to the respective signal acquired in a respective phase of the EUT. From the triad of amplitudes P1, P2, P3, amplitude proportion values P1%, P2% and P3% are derived by a normalization process, for example made by dividing each parameter by a number derived from a combination of all three parameter values, represented in FIG. 3 as module 24. As an example, each parameter can be divided by the sum of all the three parameters or it can divided by the maximum value of the three parameters or any kind of meaningful combination of the three parameters aimed at giving, as a result, a percentage or proportion indicating the parameter values relative to one another. In modules 26, 28 and 30, the three relative values P1%, P2% and P3% are compared to four thresholds t1, t2, t3 and t4 in order to identify the recorded signals as a Partial Discharge or as noise as described hereinafter. This is preferably achieved using ternary diagrams. It will be understood that the illustrated modules 20 to 30 of the acquisition unit 16 may be implemented in hardware and/or computer software as is convenient. To this end the acquisition unit 16 typically includes a computing device running suitable computer software.

Values for thresholds t1, t2, t3 and t4 can be arbitrarily or empirically chosen but preferably respect the following surrounding conditions:

t2<100−t1 & t3<100−t1−t2 & t4>=60 & t4<=80 t1>=30 & t1<50 & t3>=5

Positive identification (TRUE) of a PD event can be made as follows:
Phase-phase between phase 1 and 3: P1%>=t1 & P3%>=t2 & P2%<=t3; and/or
Phase-phase between phase 3 and 2: P3%>=t1 & P2%>=t2 & P1%<=t3; and/or
Phase-phase between phase 2 and 1: P2%>=t1 & P1%>=t2 & P3%<=t3; and/or
Phase-ground in phase 1: P1%>=t4, P3%<t2, P2%<t2; and/or
Phase-ground in phase 2: P2%>=t4, P3%<t2, P1%<t2; and/or
Phase-ground in phase 3: P3%>=t4, P1%<t2, P2%<t2

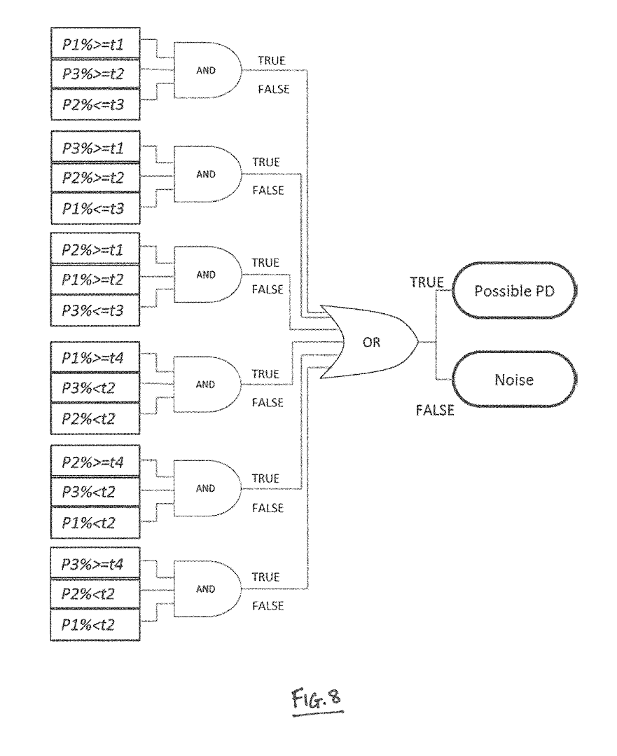

Otherwise a negative (FALSE) determination may be made (i.e. noise detection rather than a PD event). The above logic is illustrated in FIG. 8 and may be implemented by for example modules 28 and 30 of the acquisition unit 16.

The actual threshold values can vary depending on the electrical asset (EUT) being monitored.

The thresholds t1, t2, t3, t4 can be represented by segmentation of a ternary diagram, conveniently using the seven identification areas (or regions) illustrated in FIGS. 2A to 2C, which are constructed using preferred threshold values for t1, t2, t3, t4. The areas A1 to A7 may be characterized as follows:
A1: the signal recorded in phase 1 is strongly predominant and it is originated by a phase-to-ground source;
A2: the signal recorded in phase 2 is strongly predominant and it is originated by a phase-to-ground source;
A3: the signal recorded in phase 3 is strongly predominant and it is originated by a phase-to-ground source;
A4: the signals recorded in phase 1 and 2 are very similar and predominant with respect to that recorded in phase 3; the signals are originated by a phase-to-phase source;
A5: the signals recorded in phase 2 and 3 are very similar and predominant with respect to that recorded in phase 1; the signals are originated by a phase-to-phase source;
A6: the signals recorded in phase 1 and 3 are very similar and predominant with respect to that recorded in phase 2; the signals are originated by a phase-to-phase source;
A7: the signals recorded in all the three phases are very similar each other and they are coming from the same source, external to the EUT, likely noise.

The triad of acquired signals is identified as indicating a phase-to-ground phenomenon when the respective point plotted in the ternary diagram, determined by from the intersection on the diagram of the three respective percentages (or normalized values) (see FIG. 2A for an example of the determination of a point using intersection), falls into areas A1, A2 or A3.

The triad of acquired signals is identified as indicating a phase-to-phase phenomenon when the respective point plotted in the ternary diagram, coming from the intersection of the three respective percentages (or normalized values), falls into areas A4, A5 or A6.

The triad of acquired signals is identified as indicating the presence of noise when the point plotted in the ternary diagram, coming from the intersection of the three percentages (or normalized values), falls into area A7.

The segmentation of the seven areas A1 to A7, along with the thresholds values t1, t2, t3, t4, may be chosen on the basis of these concepts: a phase-ground PD event occurring in just one phase of the EUT will be significantly higher amplitude in the phase where the source is located, thus the amplitude relative concentration in the phase affected by the PD is significantly higher than the others; Phase to phase PD phenomena are very similar on two phases which means that they have a similar amplitude value. The relevant amplitude concentration value will be almost the same for the two phases affected by the PD but it will be higher than the concentration extracted in the third phase; and electromagnetic noise is generally coupled with the three phases of the EUT in a very similar way, which means that the signals detected simultaneously in the three channels will have very similar amplitude and, thus, similar concentrations.

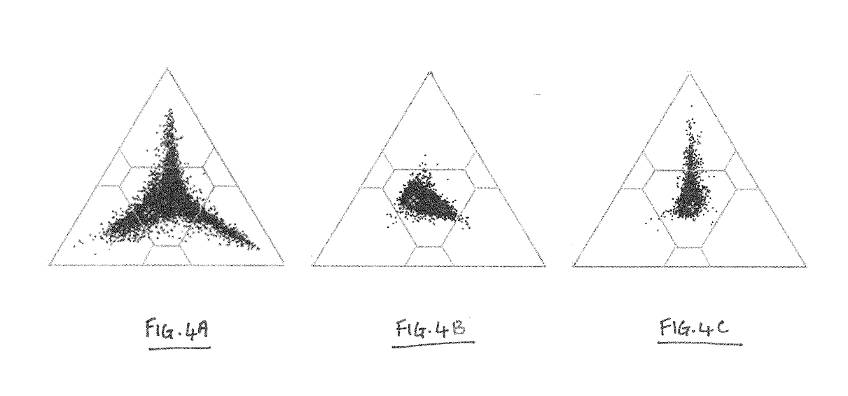

By way of example FIG. 4 shows a typical application of the techniques described above where thousands of triads of signals have been acquired and plotted in a ternary diagram based on an amplitude shape parameter with the following exemplary thresholds: T1=40, T2=40, T3=10, T4=50.

The above mentioned technique allows the automatic rejection of noise, and identification of phase to ground and phase to phase PD. This is particularly advantageous when unskilled operators use a monitoring system incorporating an embodiment of the invention: the thresholds ensure that the noise is rejected and that only predominant PD phenomena are detected.

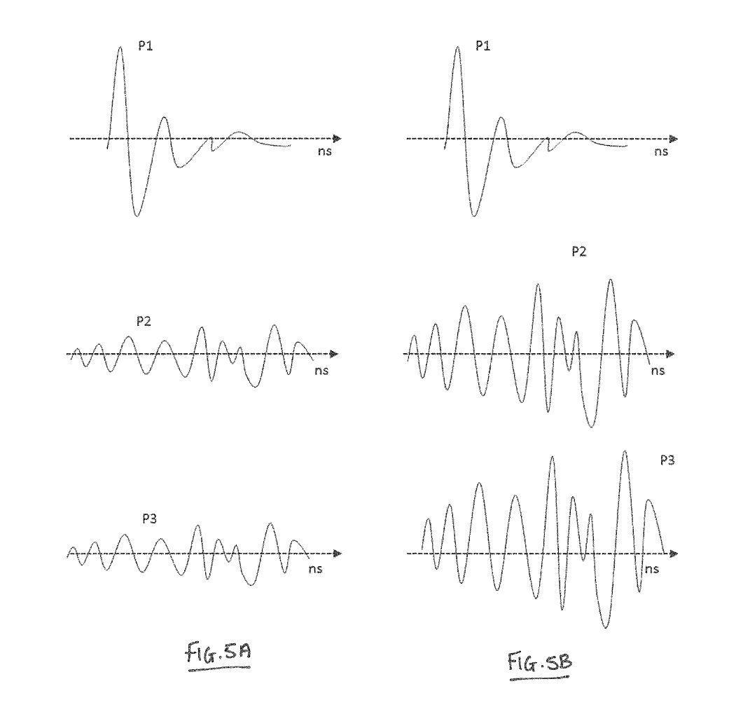

In preferred embodiments deeper and finer noise discrimination can be performed by combining the amplitude parameter with one or more additional shape parameters, or other characteristic(s), of the respective phase signals. This is particularly advantageous in cases where the background noise level is so high that the PD phenomenon amplitude becomes comparable with that of the noise, reducing the relative differences in the three relative concentrations and reducing the number of triad of pulses giving a TRUE output. In this case the amplitude parameter is still valid to reject the noise and highlight strongly predominant phenomenon but it may, at the same time, reject small PD pulses having low amplitude with respect to the noise level. FIGS. 5A (relatively low noise amplitude) and 5B (relatively high noise amplitude) show how the difference between the peak amplitude value of the PD and the noise becomes critically smaller when noise level increases.

To better discriminate noise and let also smaller PD pulses to be properly identified as PD, a method similar to that described above is preferred, based on the combination of at least two shape parameters (or other signal characteristics). The basic assumption is that even if the PD pulse has a peak value similar to that of the noise, it will have a different shape. Thus, one or more characteristic shape parameters can be extracted from the respective signal for each phase in order to allow PD pulses to be distinguished from noise based on the assumption that pulses arising from a PD event have some distinguishable characteristic(s) with respect to that of the noise, like, for example, different rise time, different power, different distance between peaks, different frequency content and so on.

In preferred embodiments, two parameters are selected for this purpose, namely: Equivalent Slope (ES): an indication of the rising slope of an acquired pulse; and Autocorrelation Power Spectral Density (APSD): an indication of the average power spectral density of the autocorrelation of each acquired pulse.

For these two parameters the relative concentrations for the three phases may be calculated and displayed in a ternary diagram, in the same manner as described above for the peak amplitude parameter. For example:

ES1%=ES1/(ES1+ES2+ES3)

ES2%=ES2/(ES1+ES2+ES3)

ES3%=ES3/(ES1+ES2+ES3)

APSD1%=APSD1/(APSD1+APSD2+APSD3)

APSD2%=APSD2/(APSD1+APSD2+APSD3)

APSD3%=APSD3/(APSD1+APSD2+APSD3),

where ES1, ES2 and ES3 are the respective ES parameters for phases 1, 2 and 3 respectively, and APSD1, APSD2 and APSD3 are the respective APSD parameters for phases 1, 2 and 3 respectively.

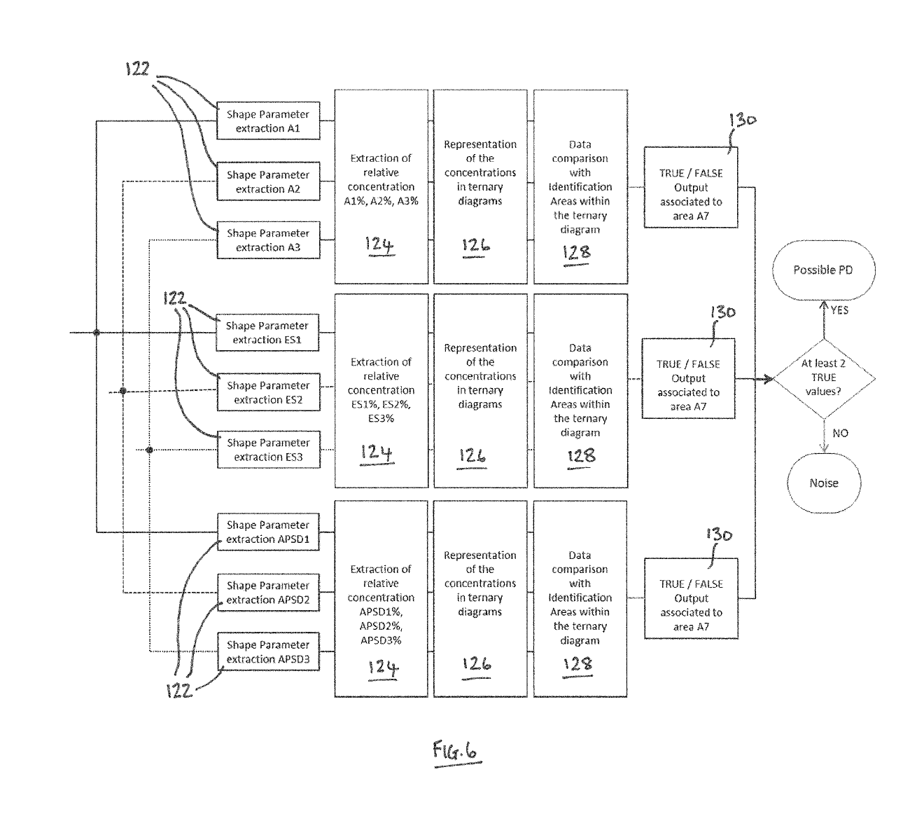

FIG. 6 illustrates the preferred method using three parameters—amplitude (A), equivalent slope (ES) and autocorrelated power spectral density (APSD). The process is conveniently the same described above in relation to FIG. 3: the respective signal parameters are extracted for each phase (modules 122); relative proportions are found for each parameter (modules 124) and compared to thresholds t1, t2, t3 and t4, conveniently by means of ternary diagrams (modules 126, 128); and a decision is made in respect of each parameter whether a PD event or noise is detected (modules 130). The modules 122 to 130 may be implemented by the data acquisition unit 16 in any convenient manner, typically by computer software.

The thresholds t1, t2, t3, t4 may be different for each parameter but preferably taking into account the following conditions:

t2<100−t1 & t3<100−t1−t2 & t4>=60 & t4<=80 t1>=30 & t1<50 & t3>=5

For each parameter, the respective normalized values for each phase undergo the comparative analysis by comparison to the relevant thresholds, and a TRUE or FALSE output decision is made for each parameter, conveniently in the same manner as described above in relation to the amplitude parameter. Still referring to FIG. 6, if at least two output values out of three (or more generally the majority or some other threshold) are TRUE, then the measured phase signal triad is identified as a possible PD. Where there are two or three FALSE outputs, the triad is identified as noise.

In cases where PD is detected, further identification as to whether it relates to phase to phase or phase to ground activity may be carried out using the following algorithm on any one of the two (or more) parameters that gave the TRUE output:
Phase-phase between phase 1 and 3: P1%>=t1 & P3%>=t2 & P2%<=t3
Phase-phase between phase 3 and 2: P3%>=t1 & P2%>=t2 & P1%<=t3
Phase-phase between phase 2 and 1: P2%>=t1 & P1%>=t2 & P3%<=t3
Phase-ground in phase 1: P1%>=t4, P3%<t2, P2%<t2
Phase-ground in phase 2: P2%>=t4, P3%<t2, P1%<t2
Phase-ground in phase 3: P3%>=t4, P1%<t2, P2%<t2

As before, the threshold values t1, t2, t3, t4 can be arbitrarily or empirically chosen and can be different for each parameter. Expert users can tune these threshold values in order to maximize the ratio between the kept and discarded signals. For non-expert users, fixed threshold values can be used aimed at rejecting all the noise and letting just predominant activities on one or two phases to pass through the algorithms. In this case the thresholds are preferably the same for all parameters and may for example be set at: t1=40, t2=40, t310 and t4=60.

It will be seen from the foregoing that the preferred method can identify and allow rejection of the electro-magnetic noise, similarly coupled with the EUT three phases, using amplitude (and/or other) parameters extracted from the respective signal sensed for each phase. Moreover identification and rejection of noise can be achieved without the need of skilled operators performing manual clustering actions. The preferred method can reject noise even if its characteristics in terms of amplitude and frequency change over the time, without the need of perform any further tuning.

The preferred method allows further improvement of noise rejection capabilities, by extracting from the noise also PD phenomena having comparable amplitude to the noise (or even smaller) and which would be normally rejected using just amplitude parameters, by means of combining the results of analysis based on multiple different parameters extracted from the respective phase signals (e.g. amplitude, equivalent slope and equivalent power).

The preferred method allows further identification of the PD pulses by indicating which is the phase where the PD source is located and if it is a source generating phase to ground or phase to phase discharges.

A preferred embodiment provides a method, in particular a real time method for automatically rejecting the electromagnetic noise affecting the measurement of Partial Discharges occurring in the insulation of medium and high voltage electrical assets, comprising at least some and preferably all of the following steps:
detecting a set of three analogue electrical signals captured simultaneously by three sensors coupled to a respective phase of the three-phase Equipment Under Test (EUT) using a trigger level as low as possible, typically below 10̂−4 V, in order to acquire pulses generated by both noise and partial discharge activities;
converting the said analogue signals into respective digital signals using simultaneous Analog-to-Digital Converters;
attributing to each digital signal an indication of the EUT phase with which the sensor is coupled;
extracting, for each digital signal, at least one parameter relating to the shape of the digital signal, resulting in a triad of shape parameters wherein each parameter corresponds to the signal acquired in a respective phase of the EUT;
converting (e.g. normalizing) the triad of shape parameters into a corresponding triad of relative values (or concentrations), e.g. expressed in ternary percentages, and for example indicating which is the most predominant shape parameter within the triad of shape parameters and how much this parameter is greater than the others.

The method preferably also includes plotting indicia on a ternary diagram or triangular plot based on said relative values. In particular each relative values in a set of three (or other number for non-3 phase applications) relative values can be plotted on the respective end-member and used to determine an intersection point on the diagram (for example as illustrated in FIG. 2);
determining the boundaries of seven areas within the ternary plot, where three of them, located close to each apex, represent single phase events, three of them, located close to the middle of each triangle side, represent occurrence of simultaneous events in two phases and 1 of them, locate at the center of the triangle, represent the occurrence of three simultaneous events on three phases, defined as the noise-area, preferably based on the following assumptions:
when one of the three concentrations has a significantly higher value with respect to the other two values, it means that the three detected signals are correlated with the occurrence of phase-to-ground event occurring in just one phase;
when two concentrations have very similar values and significantly greater than the value of the third concentration, it means that the detected signals are correlated with the occurrence of either two simultaneous phase-to-ground events in two phases or a phase-to-phase event between two phases; and
when all the three concentrations have very similar values, it means that the detected signals are correlated to the occurrence of electromagnetic noise coming from outside the EUT and equally coupled with all the three phases, and should be rejected.

The preferred embodiment includes plotting the three relative concentrations values in the ternary plot, and preferably a corresponding intersection point; identifying as noise those sets of signals generating a triad of parameters which have very similar concentration values, i.e. whose intersection falls into the noise-area of the ternary plot; identifying as phase to phase sets of signals generating a triad of parameters which have two similar concentration values and higher than the concentration of the third parameter, i.e. whose intersection falls in one of the three areas located in the middle of each side of the ternary plot; identifying as phase to ground sets of signals generating a triad of parameters which have one concentration value significantly higher than the concentration of the other two parameters, i.e. whose intersection falls in one of the three areas located close to each vertex of the ternary plot; and preferably providing a true/false output, where false indicates that the source of the three original analogue signals is a noise source and true indicates a PD event.

Preferably, the method is repeated continuously with a time interval between each repetition as short as possible, preferably not exceeding 10 ms.

It will be understood that some of the above steps may be omitted or used independently of the others as would be apparent to a skilled person.

The relative concentrations may be derived by dividing each parameter by the sum of the three parameters.

The relative concentrations may be derived by dividing each parameter by the maximum or minimum of the three parameters.

In preferred embodiments, the or each shape parameter may be a parameter indicative of any one of the amplitude of the digital signal, the rise time of the digital signal, the frequency spectrum of the digital signal, the power spectral density of the digital signal, or the autocorrelation of the digital signal. More than one such parameter may be used in the analysis. For example three different shape parameters may be determined for each acquired phase signal, a first shape parameter correlated to signal amplitude, a second shape parameter correlated to signal rise-time and a third shape parameter based on signal autocorrelation.

Advantageously, the de-noising algorithm is run multiple times (three times in the preferred embodiment) for each set of digital signals, e.g. a first time using the set of three shape parameters correlated to the amplitude, a second time using the set of three shape parameters correlated to the rise time and, a third time using the set of three shape parameters based on the signal autocorrelation, each providing a respective true/false output, one for each set of shape parameters. The identification step preferably takes into account all of the outputs and identifies the corresponding set of phase signals as noise only if at least two out three output values are false.

Embodiments of the invention may be used with a wide range of 3-phase or multi-phase electrical apparatus including but not limited to three single phase medium or high voltage cables or cable accessories, three phase oil insulated power transformers, three-phase autotransformers, three-phase resin insulated transformers, three-phase reactors, three-phase shifters, a bank of three single-phase power transformers, a bank of three single-phase autotransformers, a bank of three instrument transformers, rotating machines, three phase circuit breakers, or a module of three single phases circuit breakers.

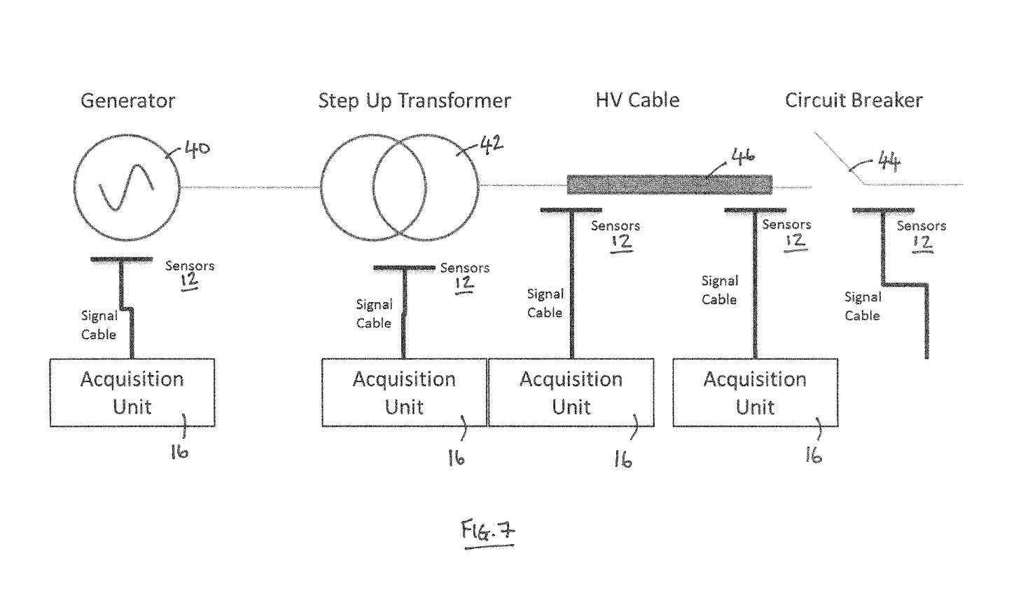

FIG. 7 shows schematically an electrical power generation system illustrating examples of where acquisition units 16 may be located in order to monitor for PD pulses. Each acquisition unit 16 may be connected to one or more sensors 12, each sensor being coupled to an EUT, for example a generator 40, step up transformer 42, auxiliary transformer (not shown), circuit breaker 44, HV cable 46, MV cable or motors (not shown), in order to detect PD in the electrical supply.

The sensors 12 may take any convenient conventional form. For example, for detecting voltage, the sensor 12 normally comprises a capacitor (not shown) and while this can measure the system voltage its defining characteristic is a high bandwidth in order to detect pulses in the MHz range (i.e. corresponding to PD events). The use of a capacitor based sensor 12 also serves to isolate the primary conductor (several kV are needed before PD can happen) and ignore the large 50/60 Hz components in favour of the mV level PD pulses. An alternative method is to monitor current pulses using a High Frequency current transformer or linear coupler (not shown). Such sensors can be fitted around the primary conductor. Alternatively still, a UHF antennae can be used for non-contact measurement. In any event, the sensors 12 should exhibit a (relatively high) bandwidth corresponding to the typical bandwidth of PD pulses.

Possible applications for embodiments of the invention are given below without limitation.

Applications (site): Distribution substation; Transmission substation; Generation plant; Industrial plant; Oil/gas plant; Offshore plants.

Applications (asset): Oil insulated Three phases Power Transformers; Oil insulated single phase transformers; Cast resin transformers; Dry type transformers; Motors; Generators; MV and HV Cables; MV and HV Circuit breakers; Current and Voltage Transformers.

Applications (measurement): Off-line Partial Discharge Measurements; On-line Partial Discharge Measurements; On-line Partial Discharge Continuous Monitoring.

The invention is not limited to the embodiment(s) described herein but can be amended or modified without departing from the scope of the present invention.

1. A method of identifying partial discharge events in a multi-phase electrical supply, the method comprising:
measuring at least one characteristic of the respective electrical signal of each phase of the electrical supply in respect of a common measurement period;
comparing a respective value representing said at least one characteristic measured in respect of each phase with a corresponding respective value of the corresponding at least one characteristic measured in respect of at least one other phase; and
determining from said comparison if the respective values of said at least one measured characteristics are indicative of a partial discharge event or of the presence of electrical noise in respect of said common measurement period.

2. A method as claimed In claim 2, wherein said measuring in respect of a common measurement period involves measuring said at least one characteristic of the respective electrical signal of each phase simultaneously.

3. A method as claimed in claim 1, wherein said comparing and said determining are performed in real time with said measuring.

4. A method as claimed in claim 1, wherein said at least one characteristic comprises a respective amplitude of the electrical signal of each phase, and wherein said amplitude is preferably the respective maximum amplitude for said measurement period.

5. (canceled)

6. A method as claimed in claim 1, wherein said at least one characteristic comprises a respective rate of change the electrical signal of each phase, and wherein said one of change preferably comprises a rate of change of a rising portion of the respective electrical signal of each phase.

7. (canceled)

8. A method as claimed in claim 1, wherein said at least one characteristic comprises a respective rise time of the electrical signal of each phase.

9. A method as claimed in claim 1, wherein said at least one characteristic comprises a power spectral density of the respective electrical signal of each phase, and wherein said power spectral density comprises an autocorrelation power spectral density.

10. (canceled)

11. A method as claimed in claim 1, wherein said at least one characteristic comprises and one or more of a respective power indication, peak-to-peak distance or frequency composition of the respective electrical signal of each phase.

12. A method as claimed in claim 1, wherein said at least one characteristic comprises a plurality of characteristics of the respective electrical signal of each phase in respect of said common measurement period.

13. A method as claimed in claim 1, wherein said measuring involves measuring at least one pulse of the respective electrical signal of each phase in respect of said common measurement period, and wherein said at least one pulse typically has a frequency associated with partial discharge events, typically in the order of MHz.

14. A method as claimed in claim 1, wherein said comparing involves comparing said at least one characteristic measured in respect of each phase with the corresponding at least one characteristic measured in respect of the or each other phase.

15. A method as claimed in claim 1, further including, before said comparing, normalizing the respective value representing said at least one characteristic of each phase, wherein said normalization involves normalizing said respective value with respect to the corresponding values for the or each other phase.

16. (canceled)

17. A method as claimed in claim 15, wherein said normalisation involves adjusting, for example dividing, said respective value with respect to a normalization value, and wherein said normalization value comprises any one or more of the sum of the respective corresponding values for each phase, a maximum value of the respective corresponding values for each phase, or other value calculated from the respective corresponding values for each phase.

18. (canceled)

19. A method as claimed in claim 15, wherein said normalization involves adjusting said respective value to be relative to the corresponding values for the other phases.

20. A method as claimed in claim 1, wherein said determining involves determining that the respective values of said at least one measured characteristics are indicative the presence of electrical noise when the respective values representing said at least one characteristic of each phase are similar to one another.

21. A method as claimed in claim 1, wherein said determining involves determining that the respective values of said at least one measured characteristics are indicative of the presence of electrical noise when the respective values representing said at least one characteristic of each phase are within a threshold amount or a respective threshold amount of each other, and wherein said threshold amount is optionally the same for each inter-phase comparison, or wherein said threshold amount is optionally different for at least one inter-phase comparison with respect to the or each other inter-phase comparison.

22-23. (canceled)

24. A method as claimed in claim 1, wherein said determining involves determining that the respective values of said at least one measured characteristics are indicative of a phase-to-ground partial discharge event in one of said phases when the respective value representing said at least one characteristic of said one phase is more than a threshold amount, or a respective threshold amount, above the respective value representing said at least one characteristic of the or each other phase.

25. A method as claimed in claim 1, wherein said determining involves determining that the respective values of said at least one measured characteristics are indicative of a phase-to-ground partial discharge event in more than one of said phases when the respective values representing said at least one characteristic of said more than one phase are more than a threshold amount, or a respective threshold amount, above the respective value representing said at least one characteristic of the or each other phase.

26. A method as claimed in claim 25, including determining that the respective values of said at least one measured characteristics are indicative of a phase-to-ground partial discharge event in more than one of said phases when the respective values representing said at least one characteristic of said more than one phase are within a threshold amount, or a respective threshold amount, of each other.

27. A method as claimed in claim 1, wherein said determining involves determining that the respective values of said at least one measured characteristics are indicative of a phase-to-phase partial discharge event between two of said phases when the respective values representing said at least one characteristic of said two phases are more than a threshold amount, or a respective threshold amount, above the respective value representing said at least one characteristic of the or each other phase.

28. A method as claimed in claim 27, including determining that the respective values of said at least one measured characteristics are indicative of a phase-to-phase partial discharge event in said two phases when the respective values representing said at least one characteristic of said two phases are within a threshold amount, or a respective threshold amount, of each other.

29. (canceled)

30. A method as claimed in claim 15, further including plotting a point corresponding to said normalized values, and/or a value derived from said normalized values, e.g. a point of intersection, on a ternary diagram in which each of three phases of said electrical supply corresponds with a respective end member of the ternary diagram, and preferably defining boundaries in said ternary diagram to create seven regions within the ternary diagram, a respective one of said areas being located at each apex of the ternary diagram and representing respective single phase partial discharge events, a respective one of said regions being located at the middle of each side of the ternary diagram and representing the occurrence of a simultaneous partial discharge event in two phases, and one of said regions being located at the centre of the ternary diagram and representing the presence of noise.

31. (canceled)

32. A method as claimed in claim 1, wherein said measuring, comparing and determining being performed in real time in respect of successive time periods, preferably at intervals of 10 ms or less.

33. A method as claimed in claim 1, wherein in respect of said measurement period, said measuring, comparing and determining is performed in respect of more than one characteristic of the respective electrical signal of each phase, said method further including determining if a partial discharge event or electrical noise is present in respect of said measurement period by aggregation of the respective individual determinations made for each of said more than one characteristic and wherein said aggregation preferably involves following the determination made for a majority of said respective individual determinations.

34. (canceled)

35. A method as claimed in claim 1, wherein said measuring involves capturing a respective analogue representation of the respective electrical signal of each phase in respect of said measurement period; and converting said analogue representation into a corresponding digital signal, said respective at least one characteristic being determined from said respective digital signal.

36. (canceled)

37. An apparatus for identifying partial discharge events in a multi-phase electrical supply, the apparatus comprising:
means for measuring at least one characteristic of the respective electrical signal of each phase of the electrical supply in respect of a common measurement period;
means for comparing a respective value representing said at least one characteristic measured in respect of each phase with a corresponding respective value of the corresponding at least one characteristic measured in respect of at least one other phase; and
means for determining from said comparison if the respective values of said at least one measured characteristics are indicative of a partial discharge event or of the presence of electrical noise in respect of said common measurement period.
